(19) United States
(12) Patent Application Publication
(10) Pub. No.: US 2010/0052020 A1
(43) Pub. Date: Mar. 4, 2010

(54) SEMICONDUCTOR SUBSTRATE AND MOS BASED PIXEL STRUCTURE

(76) Inventor: Bart DIERICKX, Edegem (BE)

Correspondence Address: BACON & THOMAS, PLLC, 625 SLATERS LANE, FOURTH FLOOR, ALEXANDRIA, VA, 22314-1176, US

(21) Appl. No.: 12/204,011

(22) Filed: Sep. 4, 2008

(51) Int. Cl. H01L 27/146; H01L 31/18

(52) U.S. Cl. 257/292; 438/59; 257/E27.133

(57) ABSTRACT

The invention relates to a semiconductor substrate 1 and a MOS based pixel structure for detecting light. The semiconductor substrate 1 comprises a base region 2 having dopants of a first conductivity type, a first region 3 having dopants of a second conductivity type, a second region 5 having dopants of the first conductivity type at a higher doping level than the base region 2, the second region 5 forming a barrier to the first region, and the second region 5 further comprising an opening 6, wherein the opening 6 is provided between the base region 2 and the first region 3. Providing such an opening 6 in the second region 5 is advantageous, since it allows provision of a low threshold voltage.

### The invention relates to a semiconductor substrate and a MOS based pixel structure for detecting light as well as a method of making and using the same

### TECHNICAL BACKGROUND

Sensors and devices based on semiconductor substrates and/or based on MOS based pixel structures fore detecting electromagnetic radiation, such as light, are known in the art, e.g. from EP 0 739 039. So-called image sensors for converting an optical image into an electrical signal are distinguished as image sensors with passive pixels or as image sensors with active pixels. Within the sensors, that are preferably implemented in CMOS- or MOS-technology, regions or layers are provided for collecting charge carrier being generated by the radiation in the semiconductor substrate. Active pixel sensors, that are passive pixel sensors with an integrated amplifier, are used today in digital photography or video recording. Other areas of use are for example cell phone cameras, web cameras and/or digital imaging for industrial purposes.

With the development of CMOS manufacturing processes, the available supply voltage for the electronic components has decreased with each generation. For example, 5 V was typically allowed for 0.5 μm CMOS manufacturing processes. The voltage then dropped to 3.3 V for 0.35 and 0.25 μm CMOS manufacturing processes, however, the voltage dropped further to 1.8 V and 1.5 V for 130 nm and 90 nm CMOS manufacturing processes. Recent CMOS manufacturing processes, such as 45 nm and below, provide a supply voltage of 1 V or even lower. This spells out a problem, as analogue circuit topologies are often required to have a supply voltage that is at least a few times the threshold voltage.

Prior art has approached this problem by introducing low, zero or negative threshold voltage transistors on some positions in the electronic circuit. However, such a solution is expensive and requires often additional manufacturing steps or can only be realized with larger electronic components, compared to conventional electronic components. Also, for avoiding parasitic conduction through the parasitic “field” MOSFET at the lateral edges of the channel, an increased distance between source and drain is required, which also leads to larger electronic component dimensions.

### SUMMARY OF THE INVENTION

It is therefore an object of the invention to provide a MOS pixel design such as a MOS-FET design or CMOS pixel design (i.e. suitable for CMOS processing) and a method of making the same that is applicable to work with a low threshold voltage.

The object of the invention is achieved by a substrate, comprising a base region, e.g. a p-type substrate, having dopants of a first conductivity type, a first region having dopants of a second conductivity type, e.g. for nMOSFETS, a second region having dopants of the first conductivity type at a higher doping level than the base region, the second region forming a barrier between the base region and the first region, e.g. a p-well, surrounding the nMOSFETS and separating them from the “base” or substrate, and the second region further comprising an opening, wherein the opening is provided between the base region and the first region. The substrate can be e.g. a semiconductor substrate such as SI, SOI, SOS, hybrid, silicon on a non-semiconductor, etc.

Accordingly, it an essential idea of the invention that the second region comprises an opening, which means that the additional dopants of the first conductivity type, which result in a higher level of doping in the second region than in the base region, are omitted in the opening. The opening therefore defines a fourth region which is a part of the substrate and hence is doped with dopants of the first conductivity type. This means further that a depletion layer, or a layer where the electric field is substantial, is created outside the confines of the second region. Such a depletion layer, which is present in the substrate and also in the fourth region and borders on the second region, forms a barrier between the base region and the first region. Providing such a opening in the second region is advantageous, since it allows provision of a low threshold voltage. Further, the invention allows for a simple manufacturing process of such a semiconductor device, e.g. such a MOSFET or a MOS pixel or a pixel having such a MOSFET or a pixel made by CMOS processing.

According to another preferred embodiment of the invention, the photodiode region, e.g. n type, is not separated from the base/substrate by the barrier region. Preferably the opening in the barrier region is small, so that the barrier remains effective. The barrier is adapted for impeding the diffusion of the charge carriers to the first region. Hence the first region is preferably adapted for not collecting the charge carriers. The photo carriers which are generated by a radiation in the semiconductor substrate can be collected elsewhere. In other words, the barrier prevents the charge carriers, which are generated by radiation in the semiconductor substrate, from diffusion to the first region.

Also the hole in the barrier layer preferably impedes carrier collection. Hence, according to a preferred embodiment of the invention, the size of the opening is adapted for impeding the diffusion of the charge carriers to the first region. This means that the depletion layer forming a barrier to the first region, which borders on the second region, is not interrupted by the small hole in the dopant concentration of the barrier layer. This can be achieved by the condition that the opening in the second region is not too wide. In this way, the depletion layer, which borders on the second region and the opening, acts as a barrier to charge carriers for impeding the diffusion into the first region.

According to another preferred embodiment of the invention, the substrate, e.g. semiconductor substrate further comprises a third region or photodiode region having dopants of the second conductivity type, wherein the third region is adapted for collecting charge carriers, which are generated by radiation in the semiconductor substrate. Preferably, the first, the second and/or the third region are defined by ion implantation or diffusion or other techniques known in semiconductor manufacturing processing, such as CMOS-based processing. It is further preferred that the first, the second and/or the third region form a junction with the base region.

According to another preferred embodiment of the invention, between the base region and the third region no barrier is present or a lower barrier is present than in between the first region and the base region. It is further preferred, that between the base region and a third region substantially no barrier or a substantially lower barrier is present than in between the first region and the base region.

According to another preferred embodiment of the invention, the third region forms a junction with the base region and the first region forms a junction with the second region. It is further preferred that at least a part of the charge carriers, that are generated in the base layer underlying the first region, are collected by the third regions. According to another preferred embodiment of the invention, the third region is part of a photo transistor.

The object of the invention is further addressed by a method of use of a substrate, e.g. semiconductor substrate, according to the invention as a detector for electromagnetic radiation and/or a MOS (e.g. MOSFET based or CMOS compatible) based pixel structure for detecting light. Preferably, the detector comprises a collection junction which collects radiation generated charge carriers, and other electronic components. It is further preferred that the detector forms part of a pixel structure wherein the collection junction is realised as one electrode, source or drain, of a MOSFET. Optionally, the other electrode is tied to certain voltage,

The object of the invention is further addressed by a MOS based pixel structure with a substrate, e.g. semiconductor substrate according to the invention, wherein the base region is a p type region, the second region is a p type region of a higher doping level than the base region, and wherein the third region and the first region are n type regions. This means that the depletion layer forming the barrier to the first region, by bordering on the second region and the opening, comprises a p+p− type region—often called a “homo-junction”.

According to another preferred embodiment of the invention, a third region is the first electrode of a MOS transistor, the third region is at least partially surrounded by the channel (area below gate) of the MOS transistor, and the first electrode surrounds at least partially the channel and the first electrode. It is further preferred that the first electrode is the source or the drain of the MOS transistor, and the second electrode is the drain or the source of the MOS transistor, respectively.

These and other aspects of the invention will be apparent from and elucidated with reference to the embodiments described hereinafter.

### BRIEF DESCRIPTION OF THE DRAWINGS

In the drawings;

FIG. 1 schematically shows a semiconductor substrate according to a preferred embodiment of the invention,

FIG. 2a schematically shows a MOSFET according to another preferred embodiment of the invention in a top view,

FIG. 2b schematically shows the MOSFET according to the other preferred embodiment of the invention in a first cross-sectional view, and

FIG. 2c schematically shows the MOSFET according to the other preferred embodiment of the invention in a second cross-sectional view.

### DESCRIPTION OF THE ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

Furthermore, the terms first, second, third and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, bottom, over, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Similarly, it is to be noticed that the term “coupled”, also used in the claims, should not be interpreted as being restricted to direct connections only. The terms “coupled” and “connected”, along with their derivatives, may be used. It should be understood that these terms are not intended as synonyms for each other. Thus, the scope of the expression “a device A coupled to a device B” should not be limited to devices or systems wherein an output of device A is directly connected to an input of device B. It means that there exists a path between an output of A and an input of B which may be a path including other devices or means. “Coupled” may mean that two or more elements are either in direct physical or electrical contact, or that two or more elements are not in direct contact with each other but yet still co-operate or interact with each other.

In embodiments of the present invention, the term “substrate” or “semiconductor substrate” may include any underlying material or materials that may be used, or upon which a device, a circuit or an epitaxial layer may be formed. In other alternative embodiments, this “substrate” may include a semiconductor substrate such as e.g. doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or a Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. The substrate may be a bulk wafer (e.g. a homogeneously doped wafer), or an epi wafer, which is a bulk wafer with a separately grown epitaxial layer on top with different dopant type and or concentration. The substrate may be a composite substrate and may also be not based on silicon or not even be a semiconductor. On top of the substrate a semiconductor layer (Si or other like Amorphous Si or selenium . . . ) can be deposited. Hence the substrate can be a bulk wafer, an epitaxial wafer, an SOI wafer, or a wafer with a top layer of semiconductor on top of a different material (like glass). The very top layer of the substrate is a semiconductor.

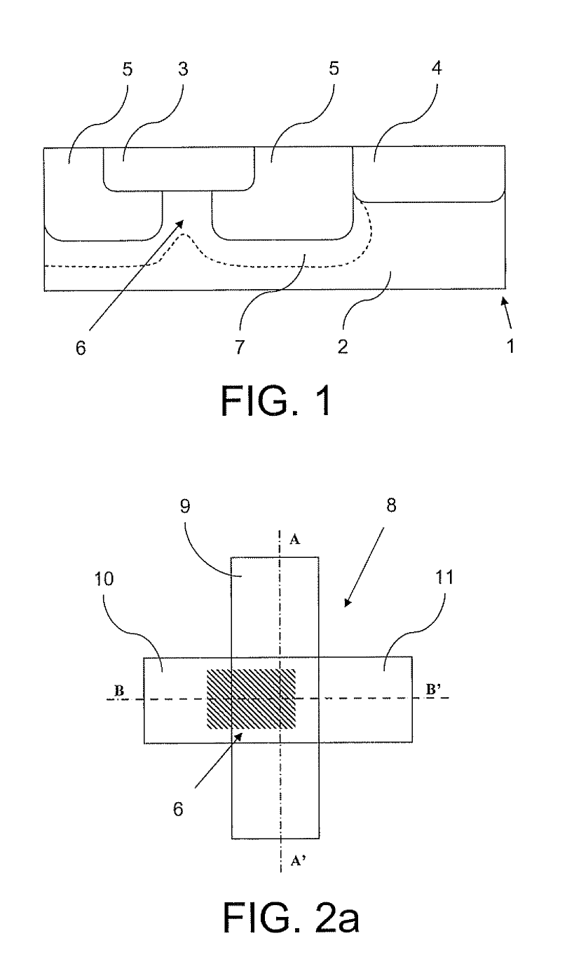

As can be seen from FIG. 1, according to a preferred embodiment of the invention, a semiconductor substrate 1 is provided, wherein the semiconductor substrate 1 comprises a base region 2 having dopants of a p type doping, i.e. of a first type. The semiconductor substrate 1 further comprises a first region 3 and a third region 4, wherein the first region 3 and the third region 4 have dopants of an n type doping, i.e. of a second type. The semiconductor substrate 1 further comprises a second region 5 having dopants of the p type doping at a higher doping level than the base region 2. The second region 5 forms a barrier to the first region 3, wherein an opening 6 is provided within the second region 5, means, that the opening 6 is provided between the base region 2 and the first region 3. Preferably, the first region 3 and the second region 4 form a junction with the base region 2. The first region 3, the second region 5 and/or the third region 4 can be provided as substrates and/or layers.

According to the preferred embodiment of the invention, the third region 4 is a collection junction for collecting the charge carriers being generated by radiation in the semi-conductor substrate 1. Preferably, the semiconductor substrate 1 forms part of a pixel structure, preferably part of a MOS based pixel structure. It is further preferred that the third region 4 is provided as a photodiode or a phototransistor. Preferably, the first region 3 forms a part of a readout circuitry for processing the signals being generated by the charge carriers being collected by the third region 4.

According to the invention, the second region 5 and the opening 6 form a barrier to the first region 3. The barrier is created by the “dimensional interaction” of the P+, P− and N regions. The hole in the barrier layer acts as a barrier as long as this hole is smaller than the depletion layer thickness that would be there if there were no barrier present. The barrier layer borders on the second layer 5, wherein the size of the opening 6 is not too wide for avoiding impeding the diffusion of the charge carriers to the first region 3. Providing such a opening 6 in the second region 5 is also advantageous, since it allows provision of a low threshold voltage.

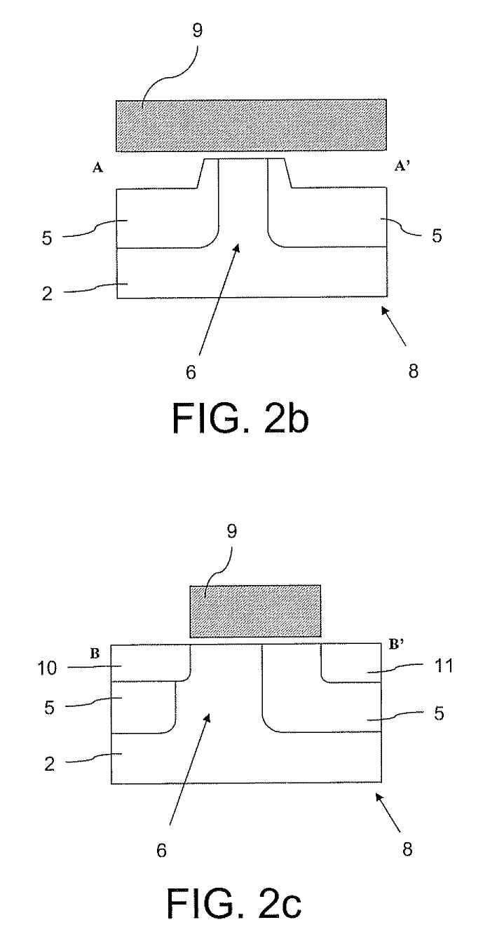

FIG. 2a schematically shows a top view of a MOSFET adapted for a low threshold voltage according to another preferred embodiment of the invention. The MOSFET 8 comprises a gate 9, a source 10 and a drain 11. As it can be seen, the opening 6 is omitted under the gate 9, but not at the edges for avoiding field leakage. This is also shown in the cross-sectional view in FIG. 2b and FIG. 2c.

According to the another preferred embodiment of the invention, the base substrate 2 is provided as a p type doping. The source 10 and the drain 11 are provided with a n+ type doping. The region 5 is provided as a p-well type doping, which is also sometimes referred to as blanket implant, threshold voltage adjust implant, field implant or other non generic names as known from the prior arts. The hole 6 is provided in the second region 5. The regions 10, 11 and the area under the gate 9 provide the third region. FIG. 2c shows a more detailed view of the third region. In other words, the p-well is omitted under the gate 9, but not at the edges, for avoiding field leakage.

The pixel structure described above can be used in a detector for electromagnetic radiation including a semiconductor substrate having dopants of a first conductivity type, wherein the substrate has a base region having dopants of a first conductivity type, a first region having dopants of a second conductivity type, a second region having dopants of the first conductivity type at a higher doping level than the base region, the second region forming a barrier to the first region, and the second region further comprising an opening, wherein the opening is provided between the base region and the first region.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practising the claimed invention, from a study of the drawings, the disclosure, and the appended claims. The mere fact that certain measures are recited in mutually different dependent claims does not indicate that a combination of these measured cannot be used to advantage. Any reference signs in the claims should not be construed as limiting the scope.

1. MOS based pixel structure, with a substrate, comprising:
a base region (2) having dopants of a first conductivity type;
a first region (3) having dopants of a second conductivity type;
a second region (5) having dopants of the first conductivity type at a higher doping level than the base region (2),
the second region (5) forming a barrier to the first region, and
the second region (5) further comprising an opening (6), wherein
the opening (6) is provided between the base region (2) and the first region (3).

2. MOS based pixel structure according to claim 1, wherein the base region (2) is a p type substrate, the second region (5) is a p type region of a higher doping level than the base region (2), and wherein the first region (3) is an n type region.

3. MOS based pixel structure according to claim 1, wherein the first region (3) can collect charge, which is generated by radiation in the substrate (1), and wherein the barrier is adapted for impeding the diffusion of the charge carriers to the first region (3).

4. MOS based pixel structure according to claim 1, wherein the size of the opening (6) is adapted for impeding the diffusion of the charge carriers to the first region (3).

5. MOS based pixel structure according to claim 1, further comprising a third region (4) having dopants of the second conductivity type, wherein the third region (4) is an n-type region and is adapted for collecting charge carriers, which are generated by radiation in the substrate (1).

6. MOS based pixel structure according to claim 5, wherein between the base region (2) and the third region (4) no barrier is present or lower barrier than in between the first region (3) and the base region (2) is present.

7. MOS based pixel structure according to claim 5, where in the third region (4) forms a junction with the base region (2) and the first region (3) forms a junction with the second region (5).

8. MOS based pixel structure according to claim 5, wherein the third region (4) is part of a phototransistor.

9. MOS based pixel structure according to claim 5, wherein the third region (4) is the first electrode of a MOS transistor, the third region (4) is at least partially surrounded by the gate of the MOS transistor, and the first electrode surrounds at least partially the gate and the first electrode.

10. MOS based pixel structure according to claim 1, wherein the first electrode is the source or the drain of the MOS transistor and the second electrode is the drain or the source of the MOS transistor, respectively.

11. A detector having a substrate comprising:
a base region (2) having dopants of a first conductivity type;
a first region (3) having dopants of a second conductivity type;
a second region (5) having dopants of the first conductivity type at a higher doping level than the base region (2),
the second region (5) forming a barrier to the first region, and
the second region (5) further comprising an opening (6), wherein
the opening (6) is provided between the base region (2) and the first region (3).

12. Detector according to claim 11, wherein the first region (3) can collect charge, which is generated by radiation in the substrate (1), and wherein the barrier is adapted for impeding the diffusion of the charge carriers to the first region (3).

13. Detector according to claim 11, wherein the size of the opening (6) is adapted for impeding the diffusion of the charge carriers to the first region (3).

14. Detector according to claim 11, further comprising a third region (4) having dopants of the second conductivity type, wherein the third region (4) is adapted for collecting charge carriers, which are generated by radiation in the semiconductor substrate (1).

15. Detector according to claim 14, wherein between the base region (2) and the third region (4) no barrier is present or lower barrier than in between the first region (3) and the base region (2) is present.

16. Detector according to claim 14, where in the third region (4) forms a junction with the base region (2) and the first region (3) forms a junction with the second region (5).

17. Detector according to claim 14, wherein the third region (4) is part of a photo-transistor,

18. Method of making a MOS based pixel structure, on a substrate having a base region (2) with dopants of a first conductivity type; the method comprising
forming a first region (3) and doping the first region with dopants of a second conductivity type,
forming a second region (5) and doping the second region with dopants of the first conductivity type at a higher doping level than the base region (2) to form a barrier to the first region, and
forming an opening (6) in the second region (5) provided between the base regional (2) and the first region (3).

19. Method according to claim 18, wherein the base region is a p type substrate, the first region is an n type region, the second region is a p type region.
